(19) United States
(12) Patent Application Publication
(10) Pub. No.: US 2004/0071876 A1
(43) Pub. Date: Apr. 15, 2004

(54) Method for forming nanocrystalline diamond films for cold electron emission using hot filament reactor

(76) Inventors: Alexandr Tursunovich Rakhimov, Moscow (RU); Vladimir Anatolievich Samorodov, Moskovskaya obl. (RU); Nikolai Vladimir Suetin, Elektrostal (RU); Valentin Vladimirovich Pochinkin, Moscow (RU)

Correspondence Address: COLLARD & ROE, P.C., 1077 Northern Boulevard, Roslyn, NY, 11576-1696, US

(21) Appl. No.: 10/464,342

(22) Filed: Jun. 18, 2003

Related U.S. Application Data
(63) Continuation of application No. 08/690,208, filed on Jul. 25, 1996, now abandoned.

(51) Int. Cl. C23C 16/26

(52) U.S. Cl. 427/249.8

(57) ABSTRACT

A method is provided for growing diamond films on substrates for formation of cold cathodes having high electron emission at a low electric field. High and uniform electron emission properties are obtained by growing the film in a hot filament reactor and in proximity to the surface of a heated grid made of graphite or other selected materials. The grid temperature is in the range of about 800° C. to about 2000° C. Mixtures of hydrogen and carbon-containing gases are used to forms the diamond.

### BACKGROUND OF THE INVENTION

1. Field of the Invention

This invention pertains to a method for forming nanocrystalline diamond films to be used for cold emission of electrons. More particularly, apparatus and method are disclosed for depositing such nanocrystalline diamond films on insulating or non-insulating substrates using a hot-filament chemical vapor deposition (CVD) process.

2. Description of the Related Art

Field emitters are used as electron sources in such applications as electron microscopes, flat panel displays, light sources and other vacuum electronics applications. In cathodoluminescence-based flat panel displays or field emission displays (FEDs), an array of field emitters acts as cold electron sources for the many pixels in a matrix display. The emission of each cold electron source is controlled by output voltages generated by solid state driver circuits. FED panels use color-emissive phosphors which are energized by emission from the array of field emitters. FED panels offer the potential for being energy-efficient. bright and providing saturated colors similar to those of a cathode ray tube (CRT). Such emitters have been reviewed in the article “Diamond-based field emission flat panel displays,” Solid State Tech., May, 1995, p. 71. The characteristics needed for the cathode have been discussed in the article “Field Emission Characteristic Requirements for Field Emission Displays,” 1994 Int'l Display Res. Conf., Soc. for Info. Display, October 1994.

Deposition of polycrystalline diamond films using a hot filament method has been discussed in many papers. For example, deposition of thin films on a large area has been discussed in the article “Growth and Characterization of Polycrystalline Diamond Thin Films Utilizing Four-Hot-Filament CVD Process”, Diamond Films and Technology, vol.5, N.2, 1995, p.67. The electron emission properties of diamond films prepared by this method have not been reported. In the paper “Microstructure and Field Emission of Diamond Particles on Silicon Tips,” Applied Surface Science 87/88 (1995), pp. 24-30, the microstructure of diamond particles deposited on silicon tips was reported and the field emission properties of the diamond-coated silicon was presented. The authors report that diamond coatings grown on the sharpened silicon tips using a hot filament CVD technique resulted in two types of coatings: nearly spherical single diamond particles grown on the very end of a tip, and an almost continuous film of coalesced particles in a film-type coating of a tip. The effective work function of the diamond coatings was in the range of 1 eV and the average size of crystallites was in the range from 10 nm to 100 nm. The authors do not report film deposition on flat surfaces. The conditions for diamond film growth are also discussed in a paper by E. I. Gigargizov et al, Materials Letters, 17, n. 1,2, pp. 61-63, 1993.

Although it is known that diamond films can be grown by hot filament methods and that electron emission can be obtained from diamond grown with a hot filament, a method for forming diamond films having high electron emission per unit area which is uniform over a significant area of a flat surface is needed. The method should also allow the formation of diamond thin films at an economical rate of growth.

### SUMMARY OF THE INVENTION

We have discovered a method and a range of operating conditions for use in the method of deposition of diamond thin films by chemical vapor deposition using a hot filament. A heated grid surface in proximity to the growing film allows films having nanocrystalline structure which leads to effective cold electron emission over a significant area. The method can produce diamond films on insulating or non-insulating substrates The films have a high density of emitting centers, volt-ampere characteristics which produce high current densities per unit area at low electric field strength and uniformity of electron emission over the surface.

The method includes placing a substrate in a reactor with provisions to heat the substrate to a selected temperature range. A hot filament is placed in the reactor and is used for gas activation and to heat a grid which is between the filament and the substrate. For a silicon substrate, for example, the substrate and grid are heated to selected temperatures and hydrogen is introduced into the reactor to remove the silicon oxide coating from the silicon. Then hydrogen and a carbon-containing gas such as methane are introduced to allow a silicon carbide layer to form on the silicon. Preferably, the methane concentration is then reduced, while maintaining the same temperature range, to allow a diamond film to grow on the substrate. Finally, the film is contacted with hydrogen again. Tests show that if the grid temperature and substrate temperature range are properly selected, a film having very efficient electron emission properties is produced.

### BRIEF DESCRIPTION OF THE DRAWINGS

A better understanding of the present invention can be obtained when the following detailed description of the preferred embodiment is considered in conjunction with the following drawings, among which:

FIG. 1 is a sketch of a deposition system suitable for the method of this invention.

FIG. 2 is a sketch of a grid which can be used in one embodiment of the invention.

FIG. 3 is a scanning electron microscope image of a nanocrystalline diamond film grown by the method of this invention.

FIG. 4 is a graph of electrical current emitted from the surface of a diamond film grown by the method of this invention as a function of electric field strength at the surface of the film.

FIG. 5 is an image of emission sites on the surface of a film grown by the method of this invention.

### DETAILED DESCRIPTION OF THE INVENTION

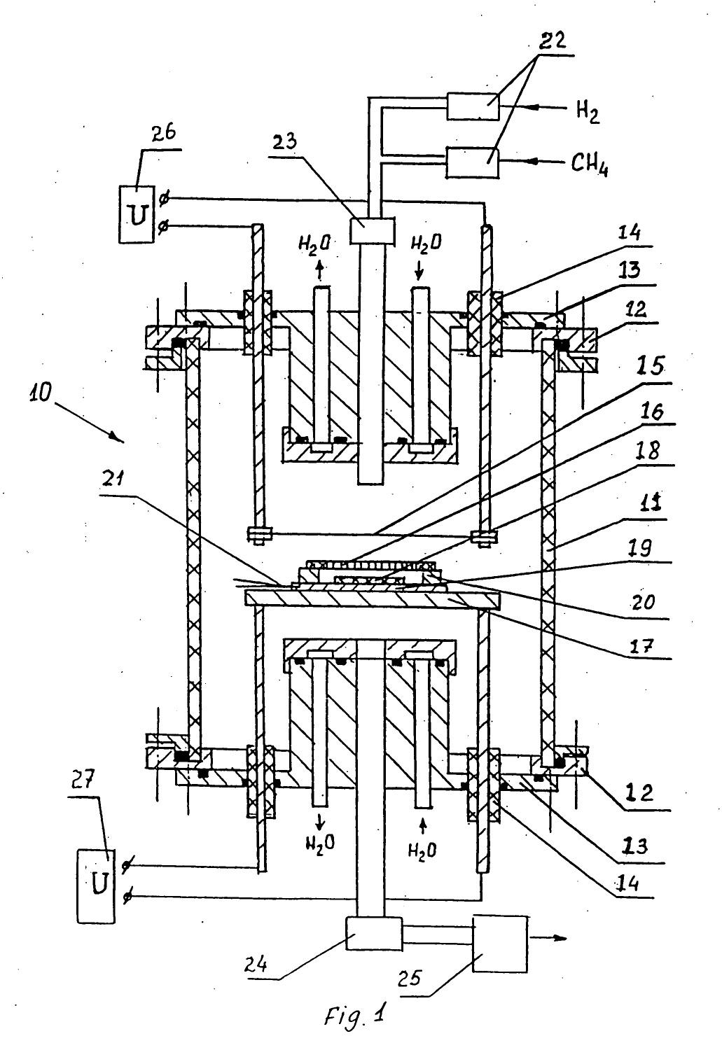

Referring to FIG. 1, a schematic diagram of a deposition system for depositing films using the hot filament method is shown. Deposition system 10 comprises reactor tube 11, preferably made from quartz, closed and sealed by flanges 12 and 13. Flanges 12 and 13 allow circulation of water for cooling when needed. Hot filament 15 and substrate heater 17 are heated by electrical power conducted through insulators 14 from power supplies 26 and 27. Tungsten wire may be used for filament 15. The wire usually will have a diameter in the range from 0.5 to 1.0 mm and will be in the form of a spiral. Several parallel spiral wires may also be used. It should be noted that increasing the wire diameter at constant filament temperature will increase the rate of surface chemical activation processes.

Vacuum pump 25 provides vacuum of 10⁻⁴ torr. Outlet gas flows through regulator 24. Working gases such as hydrogen (H₂) and methane (CH₄) are supplied through electronic mass-flow controller 22 and buffer volume 23. Other carbon-containing gases known to be suitable for deposition of diamond films may be used along with or instead of methane. Typical gas pressure is within the range of about 5 torr to about 100 torr and corresponding gas flow rate is normally maintained in the range from about 50 standard cu cm/min (sccm) to about 600 sccm during growth of diamond or any other carbon-containing films on the substrate. Methane content in the hydrogen mixture is preferably in the range from about 2% to about 10% during this time.

Substrate 18, which is usually a ceramic or molybdenum plate or silicon wafer, is placed on substrate holder 19 which has thermocouple 21 for controlling the substrate temperature. The substrate may be any material which is stable under conditions of film deposition, such as silicon, molybdenum, tungsten, tantalum, or ceramic material. The substrate temperature is preferably maintained within the range from about 600° C. to about 1000° C. The filament temperature is preferably in the range from about 1800° C. to about 2600° C. and this value is controlled with an optical pyrometer (not shown).

Grid 16 is made of a material resistant to high temperature and may be placed on its holder 20 between substrate 18 and filament 15. Suitable materials for grid 16 are tungsten or tantalum wire, molybdenum or perforated graphite plate. Other suitable materials include iron, nickel, cobalt and chromium.

In the embodiment of the method of this invention utilizing apparatus shown in FIG. 1, grid 16 is heated mainly by hot filament 15. Alternatively, the grid may be heated by an external source. Grid temperature is maintained at a temperature in the range from about 1000° C. to about 2000° C. during growth of a diamond film on substrate 18. Although we do not wish to be bound by the theory, it is believed that the role of grid 16 is to change the relation between concentrations of chemical radicals near the surface of substrate 18. It is believed that the concentration of hydrogen atoms decreases due to recombination processes on the hot surfaces of grid 16 when the grid temperatures is greater than about 800° C. The growth rate of the films increases at higher grid temperatures in the range of temperatures above about 800° C., but we have discovered that the diamond films grown at the lower temperatures in the range above about 800° C. have a nanocrystalline structure and exhibit enhanced cold election emission. The diamond films had low electron emission properties if the temperature of grid 16 was below about 800° C.

Grid 16 may be placed at a distance from filament 15 in the range from about 1 mm to about 10 cm. The distance selected will depend on the gas pressure, flow rate, rate of film growth desired and filament temperature. Substrate 18 is seeded for film growth by one of the standard procedures. The distance between grid 16 and substrate 18 may be determined by selecting the thickness of holder 20. In the experiments reported herein, the distance between grid 16 and the surface of substrate 18 was in the range from 0 to 3 mm. However, for any distance of the grid from the substrate, up to the distance from the hot filament to the substrate, the effect of the grid to produce a film having enhanced electron emission properties would be produced. The maximum effective distance between the grid and substrate would depend on overall growth conditions and dimensions of the openings in the grid.

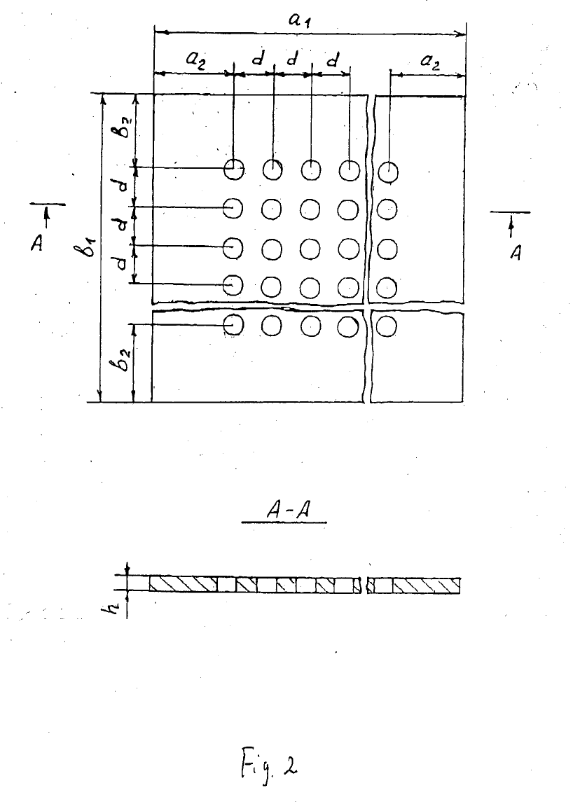

FIG. 2(a) is a sketch of the top view of one embodiment of grid 16 suitable for the method of this invention. Grid 16 may be made from a polycrystalline graphite plate having holes 30 drilled therethrough. The area of the plate having holes will normally correspond to about the area of the film to be grown on the substrate. The distance, d, between holes 30 and diameter of the holes should be properly chosen. If the diameter of the holes is less than about 0.1 mm the transparency of the grid decreases, but the effect of the grid on the film does not disappear. If the diameter of the holes is more than about 5 mm in a grid 0.5 to 2 mm thick, the effect of the grid begins to decrease. FIG. 2(b) shows a cross-section of grid 16, having thickness, h, through section A-A of FIG. 2(a) or 2(b). It was observed that increasing grid thickness, h, compensates for the adverse affect caused by increasing diameter of the holes, because this leads to increasing the influence of the grid walls. In our experiments the grid thickness was in the range from 1 to 2 mm and the diameter of the holes was in the range from 0.5 mm to 1.2 mm and the spacing, d, of the holes was in the range from 1.0 mm to 1.7 mm. Grid 16 may also be constructed from wires.

The process of deposition comprises the following steps: a substrate 16 (FIG. 1) which has been preliminarily seeded using one of the standard practices is placed on substrate holder 19 and covered with grid 16. After evacuating the chamber, hydrogen gas (H₂) is injected into reactor 11. After the gas flow rate and pressure achieve required values, power supplies 26 and 27 are switched on to heat substrate heater 17 and filament 15. The substrate and filament temperatures can be increased by increasing power supply voltages. After a time needed to allow the substrate and filament to reach required temperatures, methane gas (CH₄) is injected into reactor 11 at a selected proportion in a methane-hydrogen gas mixture. When methane gas injection begins, the deposition process begins.

The deposition process on a silicon substrate includes four stages. First, a film of silicon oxide on substrate 18 must be etched or removed. This oxide-removal step preferably occurs at a substrate temperature in the range of about 600 to 1000° C. in a chamber filled with hydrogen at a pressure in the range from about 5 torr to about 300 torr. In the second stage, a methane-hydrogen gas mixture is injected into chamber 11 to provide a methane concentration in the range from about 5% to 20% in the mixture. During this stage of the process, silicon carbide is formed on the substrate surface. This step of silicon carbide formation improves the adhesion of a diamond film to silicon substrate 18. Also, it has been found that the silicon carbide layer appears to improve electron injection performance from the silicon substrate to the diamond film and increases electron emission from the diamond film grown during the third stage. In the third stage, polycrystalline diamond is grown on the substrate surface. In this stage, the methane concentration in the gas mixture is reduced to the range from about 2% to about 8%.

Using the process described above, a thin nanocrystalline diamond film is grown on substrate 18. The deposition rate of the film is normally up to about 0.5 microns/hour. The rate increases when the distance from substrate 18 to hot filament 15 is decreased. The distance between grid 16 and hot filament 15 may be varied from about 1 mm to about 10 cm, depending on gas pressure, flow rate, growth rate desired and filament temperature. The thickness of the film grown is determined by the film growth time, and the thickness is normally increased to about 0.2 to 2.0 microns. During stage 4 of the deposition process, the gas flowing through chamber 11 is pure hydrogen. This step of film annealing normally lasts about 3 to 15 minutes.

The size of nanocrystalline diamond grains is affected by the following parameters: methane concentration in the gas mixture during film growth, gas pressure and temperatures of the substrate and the grid when the deposition occurs Typical values of the grain size is about 50 nm, as measured by scanning electron microscopy, scanning tunneling microscopy and X-ray diffractometry.

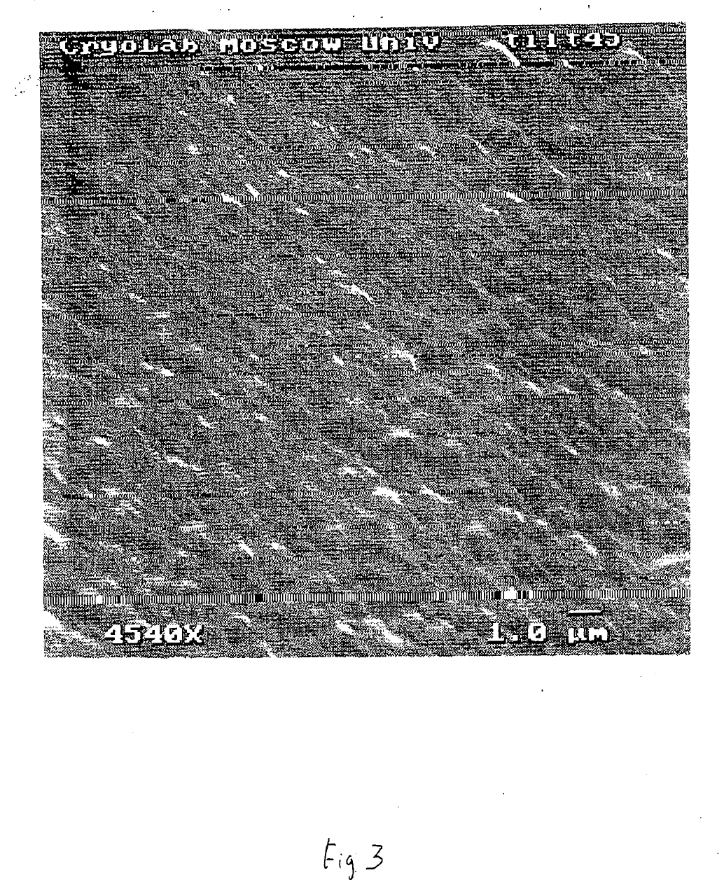

Referring to FIG. 3, a scanning electron microscope image of the surface texture is shown of a sample of thin nanocrystalline diamond film deposited by the method of this invention. The size of crystals is seen to be less than 200 nm and the crystals are essentially uniform in size over the area shown in the photograph, which is more than 20×20 microns.

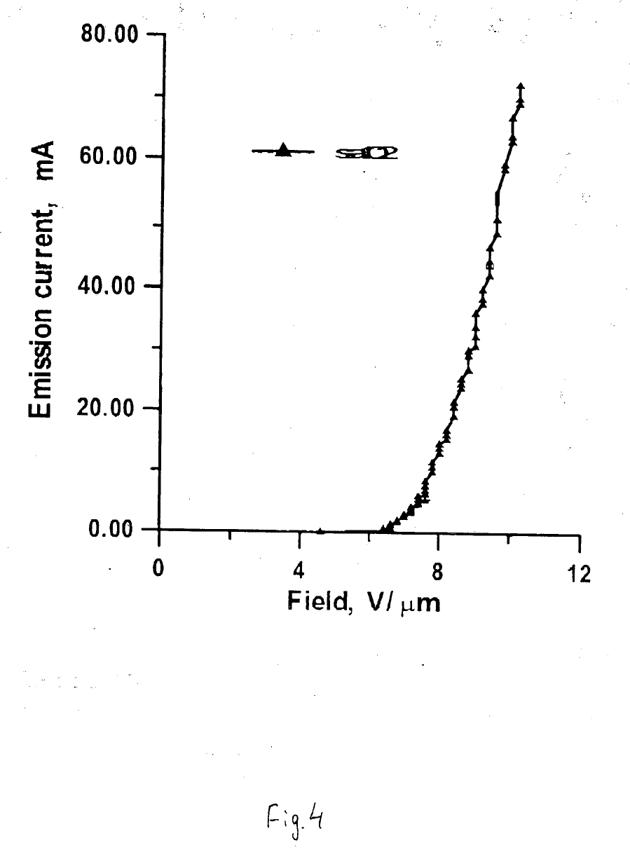

FIG. 4 is a graph of electrical current vs. electrical field strength at the surface of a diamond film for a sample made by the method of this invention. The method of measurement is described in the paper “Examination of Electron Field Emission Efficiency and Homogeneity from CVD Diamond Films,” [publication informationneeded]. The “turn-on” voltage is very low—about 8-10 V/micron, and the current density rapidly increases to a value exceeding 50 mA/sq.cm. These characteristics are satisfactory to form cold cathodes for such applications as field emission displays.

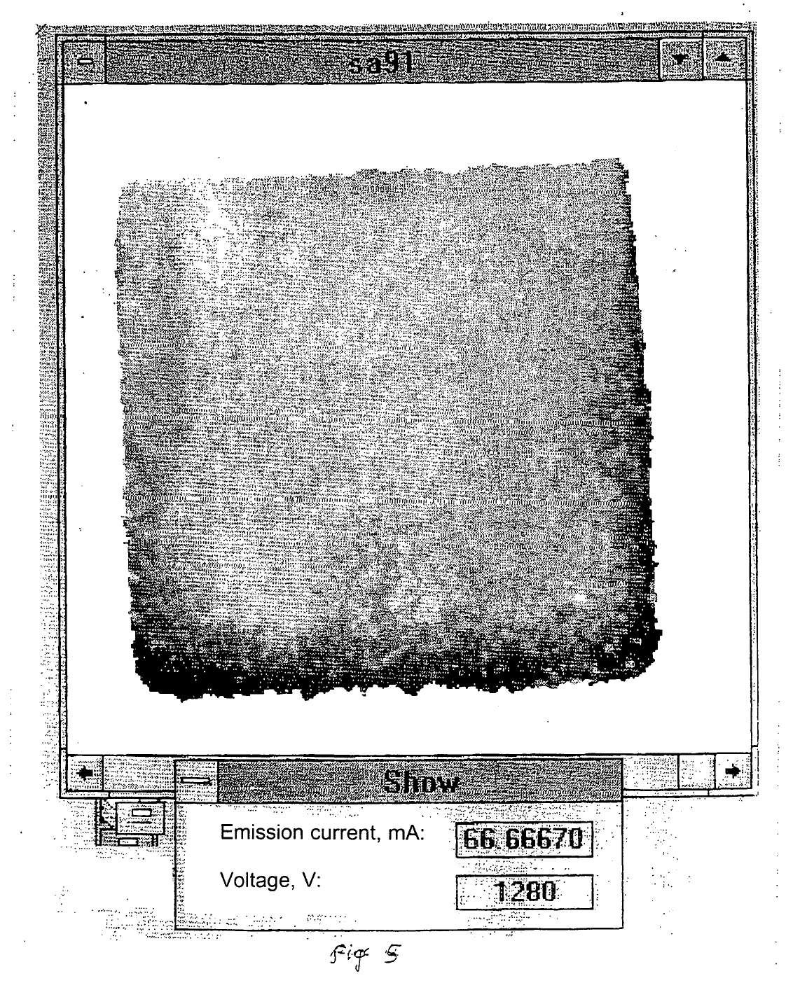

The very high density of emission sites over a substantial area of a diamond film-coated silicon substrate made by the method of this invention is illustrated in FIG. 5. This is a micrograph of a phosphor screen in apparatus developed for observing the spatial homogeneity of the diamond films, as described in the paper referenced above. The electric field at the surface of the film was about 10 V/micron. The dimensions of the bright area shown are 15 mm by 15 mm. The density of bright spots increased as electric field and emission current increased. Though there was some variation in current density along the surface on a microscopic scale, the areal uniformity of emission is sufficient for diamond film emitters used in such applications as field emission displays and light sources.

The invention has been described with reference to its preferred embodiments. Those of ordinary skill in the art may, upon reading this disclosure, appreciate changes or modifications which do not depart from the scope and spirit of the invention as described above or claimed hereafter.

What is claim is:

1. A method for depositing a diamond film for cold electron emission on a substrate in a reactor, comprising:
positioning the substrate in the reactor;
positioning a filament in the reactor at a selected distance from the substrate;
positioning a grid at a selected distance from the substrate, the grid being disposed between the substrate and the filament;
evacuating the reactor and introducing hydrogen gas into the reactor it a selected pressure;
heating the substrate and the filament such as to raise the temperature of the substrate to the range from about 600° C. to about 1000° C. and the filament to a temperature in the range from about 1800° C. to about 2800° C. and the temperature of the grid is increased to above about 600° C.;
introducing a mixture of hydrogen and a carbon-containing gas into the reactor at a selected pressure; and
growing a film on the substrate to a selected thickness.

2. The method of claim 1 wherein the substrate is comprised of silicon.

3. The method of claim 1 wherein the temperature of the filament is raised to a temperature such that the temperature of the grid is increased to the range from about 800° C. to about 1000° C.

4. The method of claim 1 wherein the temperature of the filament is raised to a temperature such that the temperature of the grid is increased to the range from about 800° C. to about 1000° C.

5. The method of claim 1 wherein the grid is comprised of graphite.

6. The method of claim 5 wherein holes in the graphite to form the grid have a diameter less than about 5 mm.

7. The method of claim 1 wherein the grid is comprised of a material selected from the group of materials consisting of tungsten, molybdenum and tantalum.

8. The method of claim 1 wherein the grid is comprised of a material selected from the group of materials consisting of iron, nickel, cobalt and chromium.

9. The method of claim 1 wherein the total pressure of pure hydrogen in the reactor is in the range from about 5 torr to about 300 torr.

10. The method of claim 1 wherein the distance from the grid to the substrate is in the range from 0 mm to the maximum effective distance between the hot filament and the substrate for enhanced electron emission properties of the film.

11. The method of claim 2 further comprising the step of reducing the amount of carbon-containing gas in the gas mixture after a carbide layer has formed on the surface and before the step of growing a diamond film on the substrate.

12. The method of claim 1 further comprising the step of introducing hydrogen gas into the reactor for a selected time after the film is grown.

13. A method for depositing a diamond film for cold electron emission on a substrate in a reactor, comprising:
positioning the substrate in the reactor and heating the substrate to a temperature in the range from about 600° C. to about 1000° C.;
positioning a grid at a selected distance from the substrate;
heating the grid to a temperature in the range from about 600° C. to about 2000° C.;
evacuating the reactor and introducing hydrogen gas into the reactor at a selected pressure;
introducing a mixture of hydrogen and a carbon-containing gas into the reactor at a selected pressure; and
growing a film on the substrate to a selected thickness.

14. The method of claim 13 wherein the substrate is silicon.

15. The method of claim 14 wherein the reactor is first filled with hydrogen at a pressure in the range from about 5 torr to about 300 torr for a time sufficient to remove a silicon oxide coating from the substrate, then a mixture of methane and hydrogen is introduced into the reactor at a methane concentration in the range from about 5 percent to about 20 percent for a time sufficient to form a silicon carbide layer on the substrate, then a mixture of hydrogen and methane is introduced into the reactor at a methane concentration in the range from about 2 percent to about 6 percent for time sufficient to grow a diamond film on the substrate to a selected thickness.

16. The method of claim 15 further comprising the step of introducing pure hydrogen into the reactor for a time sufficient to anneal the film.
